(19) United States
(12) Patent Application Publication
(10) Pub. No.: US 2004/0090747 A1
(43) Pub. Date: May 13, 2004

(54) Adjustable frame structure for carrying a circuit board

(76) Inventors: Po-Hung Wang, Chung Ho City (TW); Peng-Wei Wang, Kaohsiung City (JP); Chun-Hsiung Chiu, Taoyuan City (TW)

Correspondence Address: RABIN & BERDO, P.C., Suite 500, 1101 14th Street, N.W., Washington, DC, 20005, US

(21) Appl. No.: 10/691,701

(22) Filed: Oct. 24, 2003

(30) Foreign Application Priority Data
Oct. 25, 2002 (JP) 91217191
Oct. 25, 2002 (JP) 91217192

(51) Int. Cl. H05K 7/20

(52) U.S. Cl. 361/719

(57) ABSTRACT

An adjustable frame structure for carrying a circuit board of different sizes, includes a frame and at least one movable bar, wherein a plurality of first fasteners and at least a pair of parallel tracks are mounted on the frame, and at least one second fastener and at least two rolling pieces are formed on the at least one movable bar. The rolling pieces roll within the tracks such that the at least one movable bar can smoothly move on the frame to adjust the location of the bar on the frame according to the size of the circuit board.

### FIELD OF THE INVENTION

The present invention relates to a frame structure for carrying a circuit board to pass through a stannic furnace for wave soldering and, more specifically, to an adjustable frame structure for carrying a circuit board having at least one movable bar.

### BACKGROUND OF THE INVENTION

With great promotion of operation performance of integrated circuit (IC), the related circuit board layout design becomes more sophisticated and complicated and the manufacturing processes for plugging and tin soldering of circuit boards encounter considerable difficulties. In current production procedures of assembling circuit boards, the process for tin soldering contact pins of dual in-line package (DIP) is mainly by means of wave soldering, wherein a circuit board is firstly fixed in a frame and a transportation track is used to transmit the frame carrying the circuit board into a stannic furnace and then the molten liquid tin inside the stannic furnace is gushed up by a pump as a long tin wave and when the circuit board is obliquely transported upwardly through the stannic furnace and makes contact with the tin wave, the liquid tin will enter into the holes where the contact pins of the chip are plugged in the circuit board, fill the tin therein, and form weld spots thereon.

Refer to FIG. 1, which is a schematic perspective diagram of a first conventional frame 10 for carrying a circuit board 12. Before the wave soldering procedure, the frame 10 is used to carry the circuit board 12 to support the circuit board 12 so as to prevent the circuit board 12 from bending or deforming while passed through the stannic furnace.

Refer to FIG. 2, which is a schematic perspective diagram of a second conventional frame 10′ for carrying a circuit board 12′. The frame 10′ is a rectangular frame composed by a first side 101, a second side 102, a third side 103 and a fourth side 104, wherein the first side 101 is parallel to the third side 103 and the second side 102 is parallel to the fourth side 104. The room in the rectangular frame 10′ is equivalent to the square measure of the circuit board 12′. A supporting plate 105 is mounted at the inner edge of each of the sides of the frame 10′ and a plurality of rotating fasteners 106 are mounted on the top surface of each of the sides of the frame 10′. The circuit board 12′ is held by the supporting plates 105 of the sides of the frame 10′, and the rotating fasteners 106 on the sides of the frame 10′ are rotated onto the top surface of the circuit board 12′ to produce downward pressures to firmly fix the circuit board 12′ on the frame 10′. Afterward, the frame 10′ along with the circuit board 12′ is sent to the stannic furnace (not shown) for wave soldering.

As shown in FIG. 2, the frame 10′ is entered into the stannic furnace along the direction of an arrow X. The first side 101 which is firstly passed through the stannic furnace has a stopper 14 thereon to prevent the tin wave from contaminating the surface of the circuit board 12′ since the tin wave may be gushed higher than the height of the sides of the frame 10′.

The conventional frames have many disadvantages. Firstly, the conventional frames are only adaptable to a single specification of a circuit board. However, since tests for a new circuit board are required and the specifications of the circuit board at test stages keep to be modified, the size of the frame has to be changed. This wastes not only the materials and time for fabricating the frames but also the design costs. Furthermore, the conventional frames cannot change the direction for the circuit board to pass through the stannic furnace. Since the stopper is mounted on the first side of the frame, the circuit board has to pass the stannic furnace through the first side of the frame. However, different directions for the circuit board to pass through the stannic furnace result in different effects in the pins on the circuit board; for instance, the defects such as tin bridge or poor tin filling might occur when the circuit board passes the stannic furnace through the first side of the frame and might not occur or be reduced when the circuit board passes the stannic furnace through the second side of the frame.

Therefore, the manufacturers of circuit boards are devoted to development and improvement in the producing and manufacturing processes in order to greatly reduce manufacturing costs and to enhance the yield of wave soldering for circuit boards.

### SUMMARY OF THE INVENTION

An objective of the present invention is to provide an adjustable frame structure for carrying a circuit board, in which one bar mounted on the adjustable frame structure can be adjusted in a range such that the frame of the adjustable frame structure can accommodate circuit boards of different sizes.

Another objective of the present invention is to provide a two-side adjustable frame structure for carrying a circuit board, in which two bars mounted on the adjustable frame structure can be adjusted in a range such that the frame of the adjustable frame structure can accommodate circuit boards of different sizes.

The adjustable frame structure for carrying a circuit board disclosed in a first embodiment of this invention comprises a frame and a movable bar wherein a plurality of first fasteners are mounted on the four sides of the frame, and a pair of parallel tracks are mounted on the opposite sides of the frame, and at least one second fastener and at least two rolling pieces are mounted on the movable bar. The rolling pieces roll within the tracks such that the movable bar can move on the frame to adjust the supporting area of the frame to match up with the desired size of the circuit board.

Furthermore, the two-side adjustable frame structure for carrying a circuit board provided in a second embodiment of this invention comprises a main frame, a first movable bar and a second movable bar. The main frame is a rectangular frame composed by a first side, a second side, a third side and a fourth side, wherein the first side is parallel to the third side and the second side is parallel to the fourth side, and a first, second, third and fourth tracks are respectively mounted on the first, second, third and fourth sides of the main frame. The two ends of the first movable bar respectively slidingly cooperate with the tracks of the first side and the third side. The two ends of the second movable bar respectively slidingly cooperate with the tracks of the second side and the fourth side. An adjustable supporting area of the circuit board formed by the first movable bar, the second movable bar and a part of any two adjacent sides of the main frame is used for accommodating the circuit board.

Since the first movable bar and the second movable bar can be adjusted according to the size of the circuit board, the frame structure of this invention can carry circuit boards of different sizes. The first movable bar and the second movable bar can smoothly move on the sides of the main frame back and forth by cooperating sliding pieces of the two ends of the movable bars with tracks of the sides of the main frame, and can be fixed on the sides of the main frame by positioning pieces after the movable bars are moved to appropriate locations.

A respective immovable supporting plate is mounted at the inner edge of each of the sides of the main frame. A plurality of movable supporting plates are respectively mounted on the first movable bar and the second movable bar. The movable supporting plates can be moved back and forth on the movable bars and be fixed by positioning pieces after being moved to appropriate locations. A plurality of rotatable fasteners are mounted on the sides of the main frame and the movable supporting plates of the first and second movable bars. After the four sides of the circuit board are held by the immovable and movable supporting plates within the adjustable supporting area, the fasteners are rotated onto the circuit board to fix the circuit board on the frame structure. A stopper is mounted on one of the sides of the main frame and any side of the circuit board can be placed to the side having the stopper mounted thereon to firstly pass through the stannic furnace.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic perspective diagram of a first conventional frame for a circuit board;

FIG. 2 is a schematic perspective diagram of a second conventional frame for a circuit board;

FIG. 3 is a schematic diagram of an adjustable frame structure for carrying a circuit board in accordance with a first embodiment of this invention;

FIG. 4 is a schematic diagram of the movable bar in a first example of the adjustable frame structure for carrying a circuit board of the first embodiment of this invention;

FIG. 5 is a schematic assembling diagram of the movable bar and the parallel tracks in the first example of the adjustable frame structure for carrying a circuit board of the first embodiment of this invention;

FIG. 6 is a schematic diagram of the movable bar in a second example of the adjustable frame structure for carrying a circuit board of the first embodiment of this invention;

. FIG. 7 is a schematic assembling diagram of the movable bar and the parallel tracks in the second example of the adjustable frame structure for carrying a circuit board of the first embodiment of this invention;

FIG. 8 is a schematic diagram of a two-side adjustable frame structure for carrying a circuit board in accordance with a second embodiment of this invention;

FIG. 9 shows slidingly cooperation of one end of the movable bar with the side of the main frame in accordance with the second embodiment of this invention;

FIG. 10 shows the two-side adjustable frame structure carrying a circuit board in accordance with the second embodiment of this invention; and

FIG. 11 shows changes in the direction for the circuit board to pass through the stannic furnace in accordance with the second embodiment of this invention.

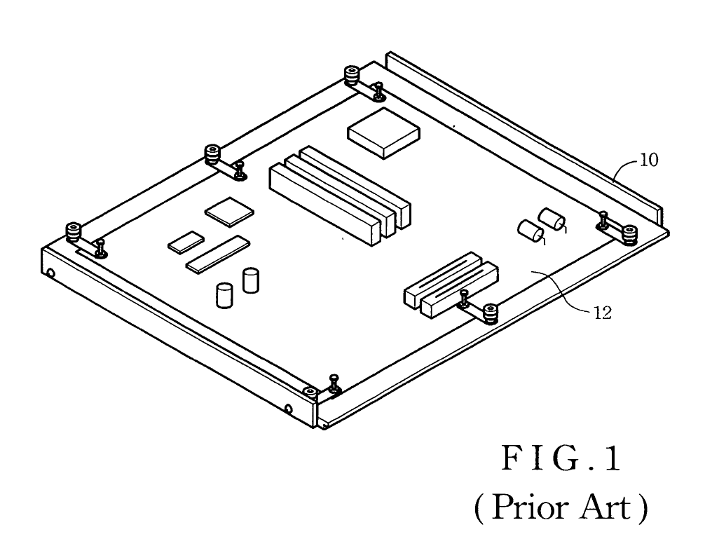

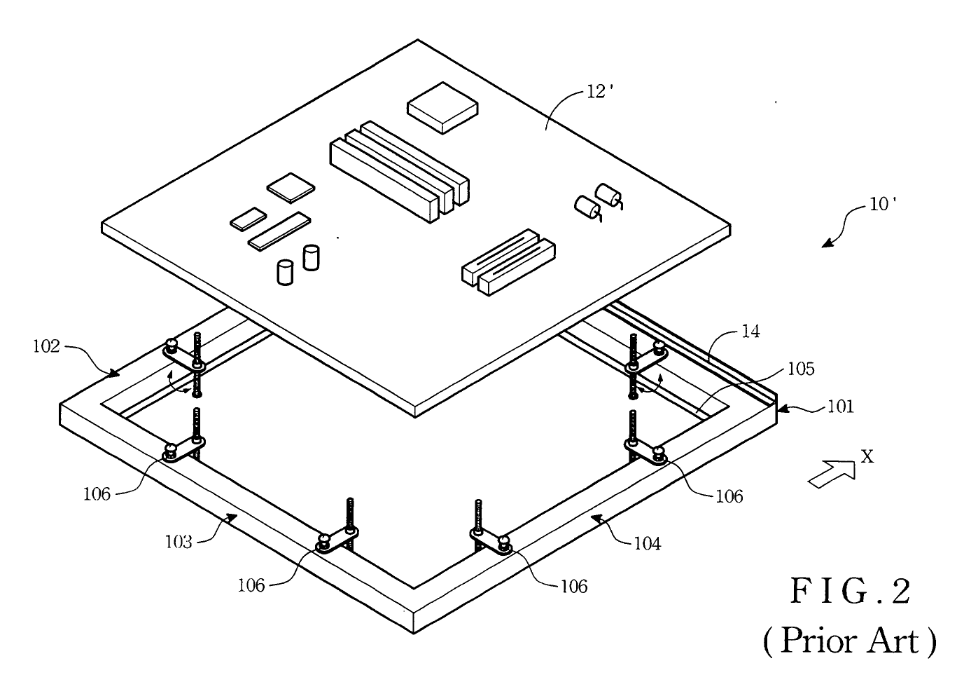

### DETAILED DESCRIPTION OF THE PREFERRED EMBODIMENTS

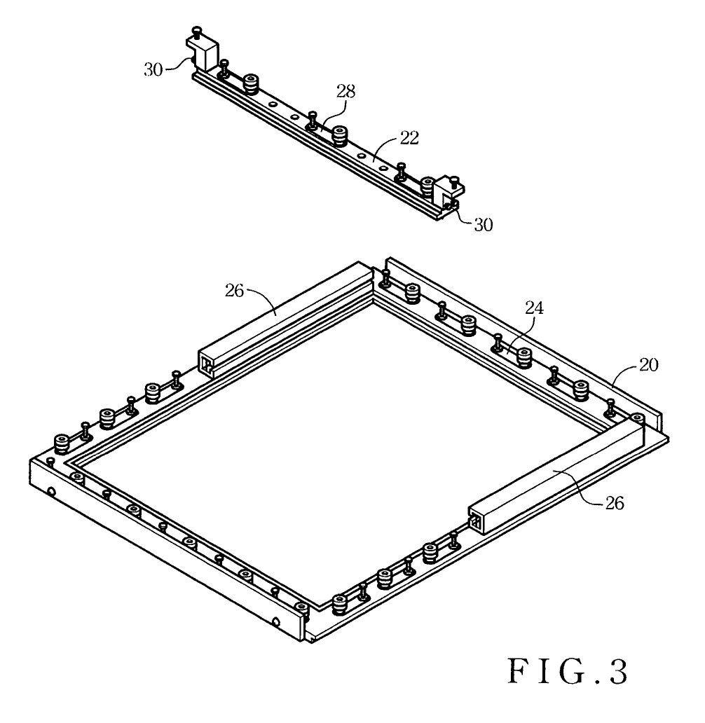

Refer to FIG. 3, which is a schematic diagram of an adjustable frame structure for carrying a circuit board in a first embodiment of this invention. The frame structure comprises a frame 20 and a movable bar 22. A plurality of first fasteners 24 are mounted on the four sides of the frame and a pair of parallel tracks 26 are mounted on the opposite sides of the frame. The movable bar 22 has at least one second fastener 28 and two rolling pieces 30 mounted thereon. One respective end of the first fasteners 24 and second fasteners 28 is pivoted onto the frame 20 and the movable bar 22 respectively, and the other respective end thereof can be rotated around the respective pivot. After the circuit board is placed in the supporting area on the frame 20, the fasteners 24 and 28 are rotated onto the circuit board to produce downward pressures on the circuit board such that the circuit board can be fixed onto the frame. The rolling pieces 30 cooperates with the tracks 26 such that the rolling pieces 30 can roll within the tracks 26 to adjust the location of the bar 22 on the frame 20 so as to carry the circuit board of different sizes. Therefore, the supporting area is adjustable.

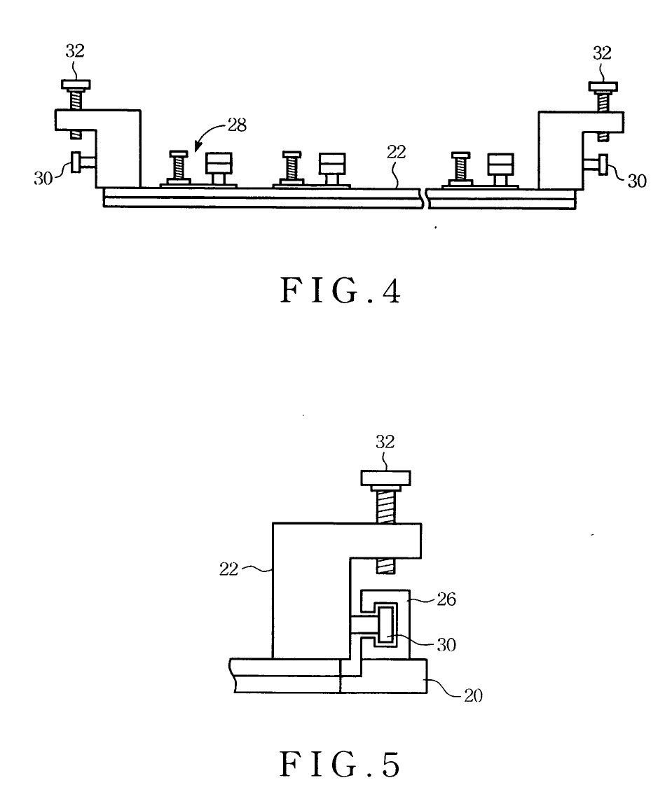

Referring to FIGS. 4 and 5, a schematic diagram of the bar and a schematic assembling diagram of the bar and the parallel tracks in a first example of the adjustable frame structure for carrying a circuit board of this invention are respectively illustrated. The bar 22 cooperates with the parallel tracks 26 of the frame 20 via the rolling pieces 30 thereof. The rolling piece 30 can be a roller. The location of the bar 22 can be adjusted by rolling the rolling pieces 30 within the parallel tracks 26 so as to reduce an applied force required to move the bar 22 on the frame 20. After the bar 22 is moved to an appropriate location where the desired circuit board are adaptable, positioning screws 32 are screwed to fix the bar 22 on the frame 20.

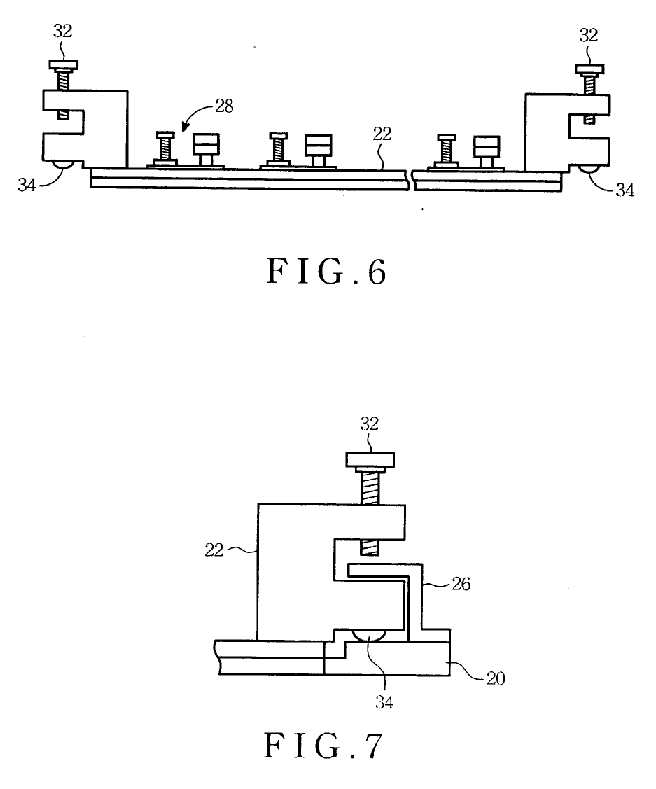

Referring to FIGS. 6 and 7, a schematic diagram of the bar and a schematic assembling diagram of the bar and the parallel tracks in a second example of the adjustable frame structure for carrying a circuit board of this invention are respectively illustrated. The bar 22 cooperates with the parallel tracks 26 of the frame 20 via a plurality of balls 34. The location of the bar 22 can be adjusted by rolling the balls 34 within the parallel tracks 26 so as to reduce an applied force required to move the bar 22 on the frame 20. After the bar 22 is moved to an appropriate location where the desired circuit board are adaptable, positioning screws 32 are screwed to fix the bar 22 on the frame 20.

The adjustable frame structure for carrying a circuit board of this embodiment can carry circuit boards of different sizes and it need not manufacture a particular frame to match up with a circuit board of certain size, especially the circuit board in prototype stage or in test stage.

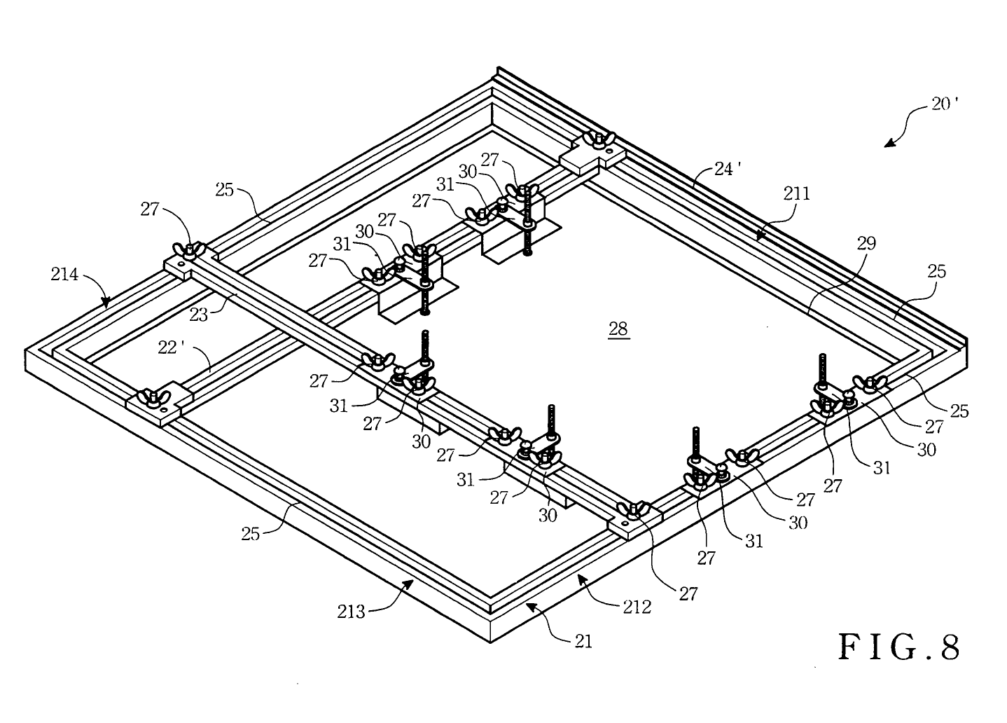

Furthermore, referring to FIG. 8, a schematic diagram of a two-side adjustable frame structure for carrying a circuit board in a second embodiment of this invention is illustrated. The two-side adjustable frame structure 20′ comprises a main frame 21, a first movable bar 22′, a second movable bar 23 and a stopper 24′, wherein the main frame 21 is a rectangular frame composed by a first side 211, a second side 212, a third side 213 and a fourth side 214, and the first side 211 is parallel to the third side 213 and the second side 212 is parallel to the fourth side 214. That is, the fist, second, third and fourth sides have their respective track 25 formed thereon.

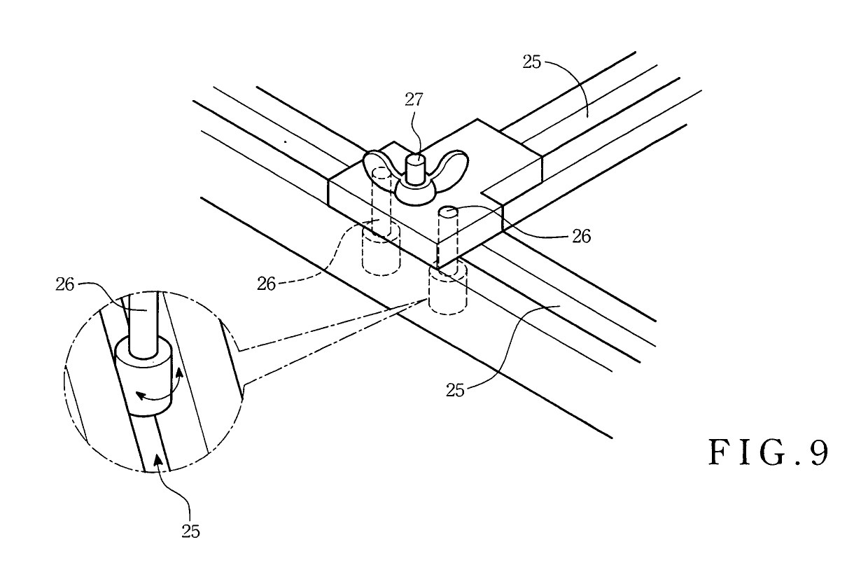

The two ends of the first movable bar 22′ respectively slidingly cooperate with the tracks 25 of the first side 211 and the third side 213. The two ends of the second movable bar 23 respectively slidingly cooperate with the tracks 25 of the second side 212 and the fourth side 214. A sliding piece such as a shaft roller 26 as shown in FIG. 9 is respectively mounted at the bottom of each of the two ends of the movable bar to slidingly cooperate with the corresponding track 25 of the side. Preferably, each end of the movable bar has two sliding pieces. A positioning piece 27 as shown in FIG. 9 is respectively mounted on each of the two ends of the movable bar to fix the movable bar on the side of the main frame 21 after the movable bar is moved to an appropriate location.

As shown in FIG. 8, a supporting area 28 of the circuit board is defined by the first movable bar 22′, the second movable bar 23 and a part of the main frame 21, and thus the supporting area is adjustable. The stopper 24′ is mounted on one of the sides of the supporting area 28. For example, the supporting area 28 of the circuit board is defined by the first movable bar 22′, the second movable bar 23, the first side 211 and the second side 212.

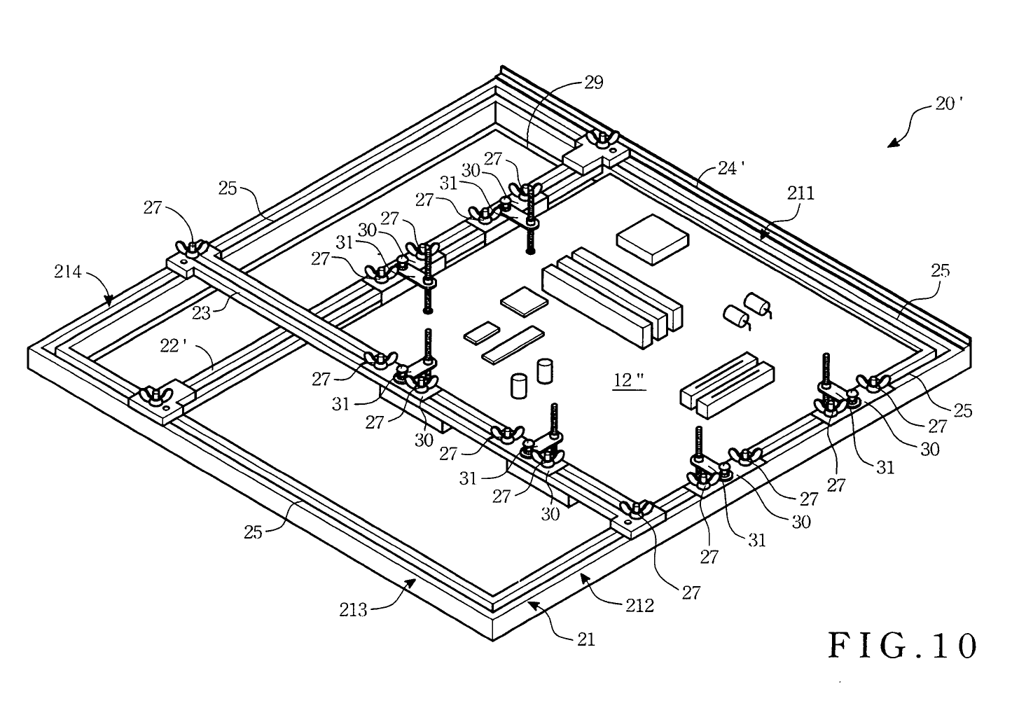

Referring to FIGS. 9 and 10, a circuit board 12″ is firstly placed in the supporting area 28 of the frame structure 20′, and then the first movable bar 22′ and the second movable bar 23 are respectively moved until the size and shape of the supporting area 28 fit to those of the circuit board 12″. Subsequently, the positioning pieces 27 are used to fix the supporting plates 30 mentioned below to the movable bars on the sides of the frame structure 20′, and then the circuit board 12″ are fixed within the supporting area 28. A respective immovable supporting plate 29 is mounted at the inner edge of each of the sides of the main frame 21. A plurality of movable supporting plates 30 are formed on the first movable bar 22′ and the second movable bar 23 respectively. The movable supporting plates 30 can be moved back and forth on the movable bars and be fixed by positioning pieces 27 after being moved to appropriate locations. Hence, the four sides of the circuit board 12″ are held by the immovable supporting plates 29 and the movable supporting plates 30 within the supporting area 28. A plurality of rotatable fasteners 31 are formed on the sides of the main frame 21 and the movable supporting plates 30 of the first and second movable bars 22′ and 23. After the four sides of the circuit board 12″ are held by the immovable and movable supporting plates 29,30 within the supporting area 28, the fasteners 31 are rotated onto the circuit board 12″ and produce downward pressures to fix the circuit board 12″ within the supporting area 28 of the frame 20.

Since the size and shape of the supporting area 28 of the frame structure 20′ for carrying a circuit board can be adjusted by moving the movable bars to carry circuit boards of different specifications, the materials and time for producing the frame structure 20′ are saved and the waste of design costs is avoided.

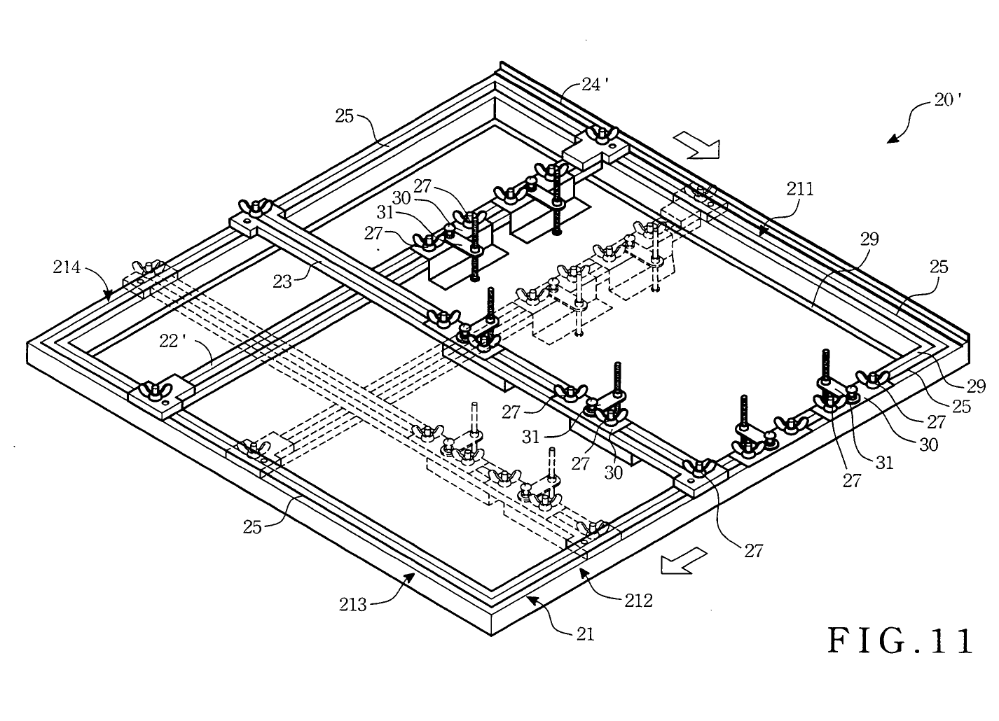

Furthermore, although the stopper 24′ of this invention is mounted on the first side 211 of the main frame 21, the direction for the circuit board 12″ to pass through the stannic furnace will not be not thus restricted. For instance, for the rectangular circuit board 12″, if the longer side of the circuit board 12″ is determined to firstly pass through the stannic furnace, the longer side of the circuit board 12″ is placed on the immovable supporting plate 29 of the first side 211 and the locations of the first and second movable bars 22′ and 23 are adjusted to accommodate the circuit board 12″. On the other hand, if the shorter side of the circuit board 12″ is determined to firstly pass through the stannic furnace, the shorter side of the circuit board 12″ is placed on the immovable supporting plate 29 of the first side 211 and the locations of the first and second movable bars 22′ and 23 are re-adjusted, as shown in FIG. 11. Hence, the frame structure of this invention can change the direction for the circuit board to pass through the stannic furnace, and an appropriate direction can be selected for the circuit board to pass through the stannic furnace at the test stage so as to reduce the defects such as tin bridge or poor tin filling occurring at the weld points of the circuit board and thus to increase the yield of wave soldering the circuit board.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed:

1. An adjustable frame structure for carrying a circuit board, comprising:
a frame;
two parallel tracks formed on the opposite sides of the frame, respectively; and
a movable bar;
wherein the movable bar can move on the frame through the tracks to adjust the location of the movable bar on the frame according to the size of the circuit board.

2. The adjustable frame structure of claim 1, further comprises a plurality of first fasteners formed on the frame.

3. The adjustable frame structure of claim 1, further comprises a rolling pieced formed on the end of the movable bar.

4. The adjustable frame structure of claim 1, further comprises a plurality of second fasteners formed on the movable bar.

5. The adjustable frame structure of claim 2, wherein the first fasteners for fixing the circuit board are formed on the four sides of the frame.

6. The adjustable frame structure of claim 4, wherein at least one second fastener for fixing the circuit board is mounted on the movable bar.

7. The adjustable frame structure of claim 1, wherein a respective rolling piece is mounted on the two ends of the movable bar to roll in the parallel tracks.

8. The adjustable frame structure of claim 7, wherein the rolling piece is a ball.

9. The adjustable frame structure of claim 7, wherein the rolling piece is a roller.

10. The adjustable frame structure of claim 6, wherein the at least one second fastener is rotated onto the circuit board and produces a downward pressure on the circuit board to fix the circuit board.

11. A two-side adjustable frame structure for carrying a circuit board, comprising:
a main frame, composed of a first side having a first track, a second side having a second track, a third side having a third track and a fourth side having a fourth track, wherein the first side is parallel to the third side and the second side is parallel to the fourth side;
a first movable bar, the two ends of which respectively slidingly cooperate with the first and third tracks; and
second movable bar, the two ends of which respectively slidingly cooperate with the second and fourth tracks;
wherein a supporting area for accommodating the circuit board is formed by the first movable bar, the second movable bar and a part of the main frame, and the locations of the first movable bar and the second movable bar on the main frame are adjusted according to the size of the circuit board.

12. The two-side adjustable frame structure of claim 11, further comprising an immovable supporting plate mounted at the inner edge of each of the sides of the main frame, and a plurality of movable supporting plates respectively mounted on the first movable bar and the second movable bar such that the circuit board is held by the immovable and movable supporting plates within the supporting area.

13. The two-side adjustable frame structure of claim 12, wherein a plurality of rotatable fasteners are mounted on the movable supporting plates to fix the circuit board within the adjustable supporting area on the frame structure.

14. The two-side adjustable frame structure of claim 11, wherein at least one first sliding piece is formed at a respective end of the first movable bar to slide in the first and third tracks of the main frame.

15. The two-side adjustable frame structure of claim 11, wherein at least one second sliding piece is formed at a respective end of the second movable bar to slide in the second and fourth tracks of the main frame.

16. The two-side adjustable frame structure of claim 14, wherein the at least one first sliding piece is a shaft roller.

17. The two-side adjustable frame structure of claim 15, wherein the at least one second sliding piece is a shaft roller.

18. The two-side adjustable frame structure of claim 11, wherein a stopper is mounted on one of the sides of the main frame.
